(19) United States
(12) Patent Application Publication
(10) Pub. No.: US 2009/0174392 A1
(43) Pub. Date: Jul. 9, 2009

(54) CIRCUIT ARRANGEMENT AND CORRESPONDING METHOD FOR VOLTAGE REFERENCE AND/OR FOR CURRENT REFERENCE

(75) Inventor: Martin Kadner, Hamburg (DE)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/298,715

(22) PCT Filed: Apr. 17, 2007
(86) PCT No.: PCT/IB2007/051373

§ 371 Date: Oct. 27, 2008

(30) Foreign Application Priority Data
Apr. 25, 2006 (EP) 06113026.6

(51) Int. Cl. G01R 19/00

(52) U.S. Cl. 324/76.11

(57) ABSTRACT

In order to further develop a circuit arrangement (100) as well as a corresponding method for voltage reference and/or for current reference in such circuit arrangement (100) in such way that any additional reference to observe the bandgap reference is not required, it is proposed to perform at least one analog built-in self test (BIST) scheme on the basis of the output of the bandgap reference.

The present invention relates to a circuit arrangement comprising at least one output stage of a bandgap reference.

The present invention further relates to a corresponding method for voltage reference and/or for current reference in such circuit arrangement.

Regarding the technological background of the present invention, reference can be made to prior art documents
U.S. Pat. No. 4,489,285 where current mirrors along with a current adder circuit are used to detect the maximum current in a particular current mirror;
U.S. Pat. No. 5,773,967 dealing with the self-monitoring and self-calibration for a reference voltage;
US 2004/0263180 A1 referring to comparing with historical values at a predetermined interval of time;
WO 2004/113937 A1; and
WO 2004/113938 A1.

However, in these respectively known arrangements an additional reference to observe the bandgap references is required.

Starting from the disadvantages and shortcomings as described above and taking the prior art as discussed into account, an object of the present invention is to further develop a circuit arrangement of the kind as described in the technical field as well as a method of the kind as described in the technical field in such way that any additional reference to observe the bandgap reference is not required.

The object of the present invention is achieved by a circuit arrangement comprising the features of claim 1 as well as by a method comprising the features of claim 7. Advantageous embodiments and expedient improvements of the present invention are disclosed in the respective dependent claims.

The present invention is based on the idea of implementing at least one analog built-in self test (BIST) scheme for band-gap reference or for voltage reference or for current reference by combining at least one current mirror and at least one current comparator. With such analog built-in self test stage being implemented as a new system, the circuit design according to the present invention as well as the method according to the present invention do not require any additional reference to observe the bandgap references.

According to a particular refinement of the present invention, the analog B[uilt-] I[n]S[elf]T[est] is used to provide an online test of references on chip.

Preferably, the analog built-in self test solves the problem of testing analog references in field. In this context, testing analog references in field means that the hardware application used by a customer is observed the whole life time of the device. If there is an incidence forcing a wrong value of reference to all internal blocks, such incidence will be recognized by the present invention.

The present invention further relates to an I[ntegrated]C[ircuit] of a chip card or of a smart card, said I[ntegrated]C[ircuit] comprising at least one circuit arrangement as described above and/or being operated according to the method as described above.

The present invention finally relates to the use of at least one circuit arrangement as described above and/or of the method as described above in at least one product including at least one voltage reference and/or at least one current reference, in particular
for online testing of the band-gap reference or of the voltage reference or of the current reference on chip and/or
for observing at least one chip against hacker attacks and life time failures.

As already discussed above, there are several options to embody as well as to improve the teaching of the present invention in an advantageous manner. To this aim, reference is made to the claims respectively dependent on claim 1 and on claim 7; further improvements, features and advantages of the present invention are explained below in more detail with reference to a preferred embodiment by way of example and to the accompanying drawings where

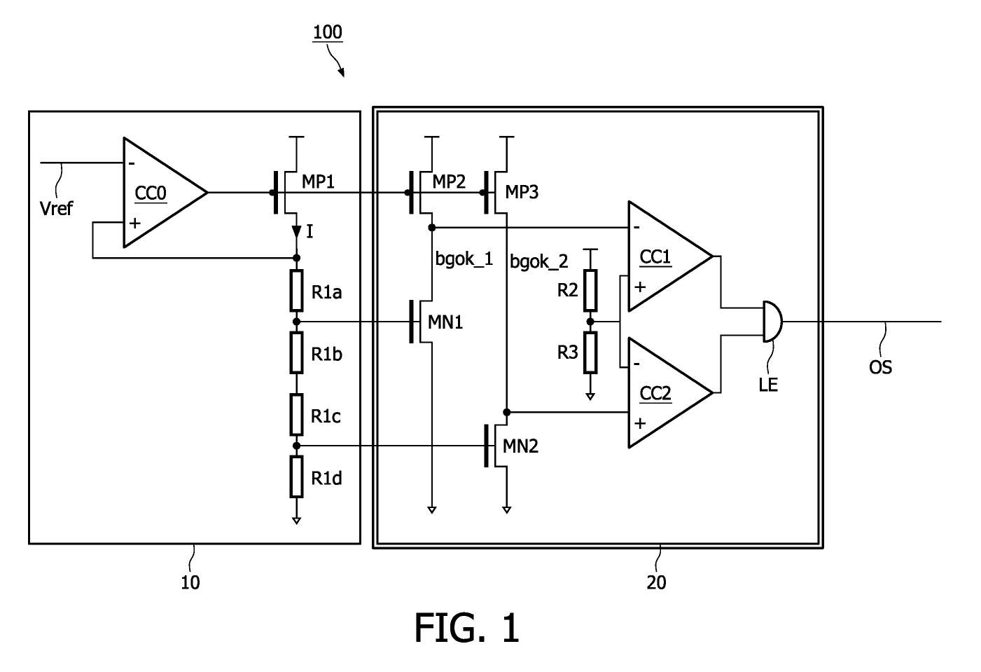

FIG. 1 schematically shows an embodiment of the circuit arrangement according to the present invention, this circuit arrangement being operated according to the method of the present invention;

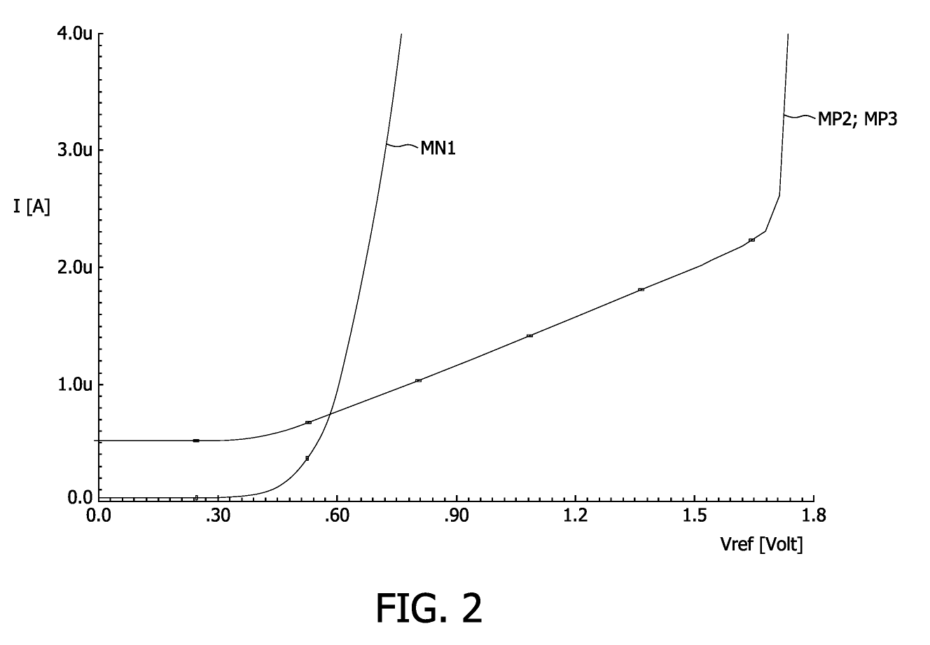

FIG. 2 diagrammatically shows the current signal through a current mirror as a function of the reference voltage, with this current mirror being part of the circuit arrangement of FIG. 1;

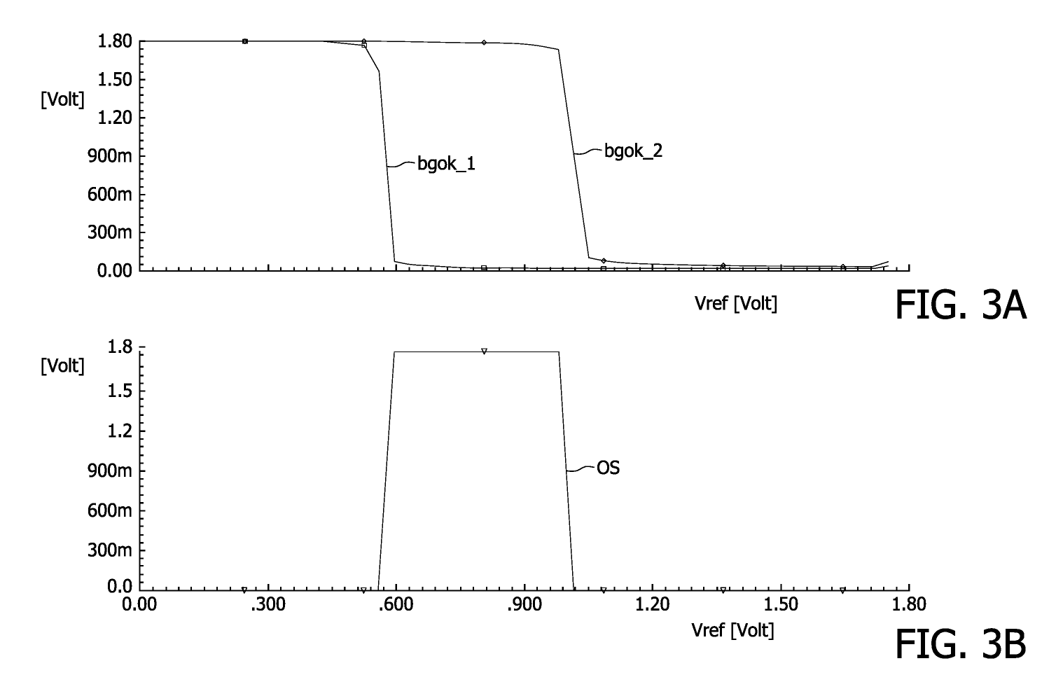

FIG. 3A diagrammatically shows the node voltage signal within the current mirror as a function of the reference voltage; and

FIG. 3B diagrammatically shows the resulting output voltage signal as a function of the reference voltage.

The same reference numerals are used for corresponding parts in FIG. 1 to FIG. 3B.

FIG. 1 shows an embodiment of the circuit arrangement 100 according to the present invention, this circuit arrangement 100 being operated according to the method of the present invention.

The circuit arrangement 100 comprises two blocks 10, 20 connected with each other wherein
the first block 10 is the output stage of a bandgap reference and
the second block 20 is the analog B[uilt-]I[n]S[elf]T[est] stage for voltage reference and/or for current reference.

The output stage 10 of the bandgap reference comprises a p-type transistor unit MP1, in particular a p-channel metal-oxide semiconductor (PMOS) or a p-type metal-oxide semiconductor field effect transistor (PMOSFET), starting to conduct in case of application of a higher voltage on its drain electrode and/or on it source electrode than on its gate electrode.

The gate electrode of this p-type transistor unit MP1 is connected to the output terminal of a comparator unit CC0 being provided with the reference voltage Vref. The drain electrode of this p-type transistor unit MP1 and/or the source electrode of this p-type transistor unit MP1 is connected to a series of for example four resistor units R1a, R1b, R1c, R1d.

The output stage 10 of the bandgap reference provides a current I which is related to the bandgap voltage reference. The analog built-in self test stage 20 uses this current I to observe the voltage references and/or the current references.

In the analog built-in self test circuit 20, the current I is copied two times by respective current mirrors MP1, MP2, MP3. Basically, such current mirror is a circuit designed to copy the current I flowing through an active device by controlling the current in another active device, keeping the output current constant regardless of loading.

More particularly, in the BIST scheme 20 as depicted in FIG. 1, the current mirrors MP1, MP2, MP3 comprise
the p-type transistor unit MP1 assigned to output stage 10 of bandgap reference,
a second p-type transistor unit MP2, in particular a second p-channel metal-oxide semiconductor (PMOS) or a second p-type metal-oxide semiconductor field effect transistor (PMOSFET), assigned to analog built-in self test stage 20, and
a third p-type transistor unit MP3, in particular a third p-channel metal-oxide semiconductor (PMOS) or a third p-type metal-oxide semiconductor field effect transistor (PMOSFET), assigned to analog built-in self test stage 20.

Two further transistor units MN1, MN2, in particular two n-type transistor units, for example two n-channel metal-oxide semiconductors (NMOS) or two n-type metal-oxide semiconductor field effect transistors (NMOSFET), are connected to the second p-type transistor unit MP2 and to the third p-type transistor unit MP3 via at least one respective gate terminal.

These two n-type transistor units MN1, MN2 work as kind of reference pulling
the first node voltage bgok_1, which is assigned to the first n-type transistor unit MN1, and
the second node voltage bgok_2, which is assigned to the second n-type transistor unit MN2,
   from the high level to the low level at a certain or (pre)determined threshold of the reference voltage Vref.

This certain or (pre)determined threshold value of the reference voltage Vref may for example be defined by the intersection of the two curves in FIG. 2 showing the relative behaviour of the currents I through the pairs MP2, MN1 and MP3, MN2 of transistor units in dependence on the reference voltage Vref. These pairs MP2, MN1 and MP3, MN2 of transistors are arranged as current comparators.

In this context, FIG. 2 refers by way of example to the first n-type transistor unit MN1; the second n-type transistor unit MN2 basically shows the same behaviour as the first n-type transistor unit MN 1; however, the second n-type transistor unit MN2 shows this essentially same behaviour at a higher value of the reference voltage Vref.

The result of this relative behaviour of the currents I ends up in the node voltages bgok_1 and bgok_2 within the respective current mirrors MP2, MN1 and MP3, MN2; the relative behaviour of these node voltages bgok_1, bgok_2 in dependence on the reference voltage Vref is depicted in FIG. 3A.

The results are detectable signals which can be combined by using two comparators CC1, CC2 comparing the node voltages bgok_1, bgok_2 with half the supply voltage Vdd (the first resistor unit R2 in the analog built-in self test circuit 20 is equal to the second resistor unit R3 in the analog built-in self test circuit 20) and a logical element LE, in particular an AND gate, at the output of the analog built-in self test circuit 20.

The accordingly developed signal OS is the reference okay signal at the output of the analog built-in self test circuit 20; this reference okay signal OS is shown in FIG. 3B in dependence on the reference voltage Vref.

The analog BIST circuit 20 is tunable by the following design values:
the ratio W/L of the channel width W to the channel length L of the oxide and metal polysilicon layer of the transistor units MN1, MN2; and/or
the resistance of the for example four resistor units R1a, R1b, R1c, R1d comprised by the output stage 10 of the bandgap reference.

### LIST OF REFERENCE NUMERALS

100 circuit arrangement
10 output stage of bandgap reference of circuit arrangement 100
20 analog built-in self test stage of circuit arrangement 100
bgok_1 node voltage signal within first pair of transistor units MP2, MN1
bgok_2 node voltage signal within second pair of transistor units MP3, MN2
CC0 comparator unit of output stage 10 of bandgap reference
CC1 first comparator unit of analog built-in self test stage 20
CC2 second comparator unit of analog built-in self test stage 20
LE logical element, in particular AND gate
MN1 first n-type transistor unit, in particular first n-channel metal-oxide semiconductor (NMOS) or first n-type metal-oxide semiconductor field effect transistor (NMOSFET), assigned to analog built-in self test stage 20
MN2 second n-type transistor unit, in particular second n-channel metal-oxide semiconductor (NMOS) or second n-type metal-oxide semiconductor field effect transistor (NMOSFET), assigned to analog built-in self test stage 20
MP1 first p-type transistor unit, in particular first p-channel metal-oxide semiconductor (PMOS) or first p-type metal-oxide semiconductor field effect transistor (PMOSFET), assigned to output stage 10 of bandgap reference
MP2 second p-type transistor unit, in particular second p-channel metal-oxide semiconductor (PMOS) or second p-type metal-oxide semiconductor field effect transistor (PMOSFET), assigned to analog built-in self test stage 20
MP3 third p-type transistor unit, in particular third p-channel metal-oxide semiconductor (PMOS) or third p-type metal-oxide semiconductor field effect transistor (PMOSFET), assigned to analog built-in self test stage 20
OS output signal, in particular reference okay signal, of analog built-in self test stage 20
R1a first resistor unit of output stage 10 of bandgap reference
R1b second resistor unit of output stage 10 of bandgap reference
R1c third resistor unit of output stage 10 of bandgap reference
R1d fourth resistor unit of output stage 10 of bandgap reference
R2 first resistor unit of analog built-in self test stage 20
R3 second resistor unit of analog built-in self test stage 20
Vref voltage reference

1. A circuit arrangement comprising at least one output stage of a bandgap reference, characterized by
at least one analog built-in self test stage for voltage reference and/or for current reference, said analog built-in self test stage being connected to the output stage of the bandgap reference.

2. The circuit arrangement according to claim 1, characterized in that the output stage of the bandgap reference comprises
at least one comparator unit (CC0) being provided with the reference voltage (Vref),
at least one first transistor unit, in particular at least one first p-type transistor unit, for example at least one first p-channel metal-oxide semiconductor (PMOS) or at least one first p-type metal-oxide semiconductor field effect transistor (PMOSFET), the gate electrode of said first transistor unit being connected to the output terminal of the comparator unit (CC0), and
a series of resistor units being connected to the drain electrode of said first transistor unit and/or to the source electrode of said first transistor unit.

3. The circuit arrangement according to claim 1, characterized in
that the output stage of the bandgap reference provides a current being related to the bandgap voltage reference, and
that the analog built-in self test stage uses said current to observe the voltage reference and/or the current reference.

4. The circuit arrangement according to claim 3, characterized in
that the current is copied at least one time, preferably two times, by at least one respective current mirror, said current mirror respectively comprising
said first transistor unit,
at least one second transistor unit, in particular at least one second p-type transistor unit, for example at least one second p-channel metal-oxide semiconductor (PMOS) or at least one second p-type metal-oxide semiconductor field effect transistor (PMOSFET), and/or
at least one third transistor unit, in particular at least one third p-type transistor unit, for example at least one third p-channel metal-oxide semiconductor (PMOS) or at least one third p-type metal-oxide semiconductor field effect transistor (PMOSFET), and
that at least one, preferably two further transistor units, in particular n-type transistor units, for example n-channel metal-oxide semiconductors (NMOS) or n-type metal-oxide semiconductor field effect transistors (NMOSFET), are connected to the second transistor unit and/or to the third transistor unit.

5. The circuit arrangement according to claim 4, characterized by combining the signals resulting from the respective current mirror by using at least one, preferably two, comparator units comparing the respective node voltage with half the supply voltage wherein at least one first resistor unit may be equal to at least one second resistor unit, with at least one logical element, in particular at least one AND gate, being arranged at the output of the analog built-in self test stage.

6. The circuit arrangement according to claim 1, characterized in that the analog built-in self test stage is tunable
by the ratio (W/L) of the channel width (W) to the channel length (L) of the further transistor units, and/or
by the resistor units of the output stage of the bandgap reference.

7. A method for voltage reference and/or for current reference in at least one circuit arrangement, characterized by
performing at least one analog built-in self test (BIST) scheme on the basis of the output of the bandgap reference.

8. The method according to claim 7, characterized by implementing the analog built-in self test (BIST) scheme by combining at least one current mirror means and at least one comparator means.

9. Chip card or smart card comprising at least one I[ntegrated]C[ircuit] with at least one circuit arrangement according to claim 1 and/or being operated according to the method according to claim 7.

10. (canceled)
